(19) United States
(12) Patent Application Publication
(10) Pub. No.: US 2026/0362836 A1
(43) Pub. Date: Nov. 12, 2026

(54) ULTRAVIOLET (UV) SENSOR DEVICES FOR DETERMINATION OF UV INDEX

(71) Applicant: Analog Devices, Inc., Wilmington, MA (US)

(72) Inventors: I-Chun HUANG, Stoneham, MA (US); Matthew EMSLEY, North Reading, MA (US); Yang QIAN, Fremont, CA (US)

(21) Appl. No.: 19/673,647

(22) Filed: May 11, 2026

Related U.S. Application Data
(60) Provisional application No. 63/803,346, filed on May 9, 2025.

(51) Int. Cl. H10F 39/00; G02B 5/20; G02B 5/28; H10F 39/18

(52) U.S. Cl. CPC H10F 39/8053; G02B 5/208; G02B 5/283; G02B 5/285; H10F 39/014; H10F 39/024; H10F 39/18

(57) ABSTRACT

Aspects of the present disclosure includes a sensor device having a substrate, a photodiode device formed on the substrate, the photodiode device being configured to generate a photocurrent in response to being irradiated with sunlight, and an optical filter device formed on a passivation layer and deposited over the photodiode device, the optical filter device having a first plurality of layers of a conducting material, a second plurality of layers of a dielectric material, wherein the first plurality of layers and the second plurality of layers stacked alternatingly, and wherein the optical filter device is configured to match at least a portion of the erythemal curve, resulting in the photocurrent generated by the photodiode device being a representation of a UV index.

### CROSS-REFERENCE TO RELATED APPLICATIONS

The current application claims priority to, and the benefit of, U.S. Provisional Application No. 63/803,346 filed May 9, 2025 and entitled “ULTRAVIOLET (UV) SENSOR DEVICES FOR DETERMINATION OF UV INDEX,” the contents of which are hereby incorporated by reference in their entireties.

### BACKGROUND

Over-exposure of ultra-violet (UV) light is a reason for skin aging and even skin cancer. A real-time UV index detector could help with monitoring and preventing the damage on skin. Erythema action spectrum is used as a weighting function to calculate the UV index. However, its abrupt change in sensitivity around 310 nanometer (nm) wavelength makes it difficult in implementation using a single chip. As a result, existing chip-scale UV index sensors do not have accurate readings, and/or have to rely on extra calibration with addition information like location, time, altitude, and/or other factors. In contrast, the instrument-scale UV index detectors can be accurate with more complicated system design. However, they may be expensive and bulky. As such, improvements in UV light detection with respect to human exposure is desirable.

### SUMMARY

Aspects of the present disclosure includes a sensor device having a substrate, a photodiode device formed on the substrate, the photodiode device being configured to generate a photocurrent in response to being irradiated with sunlight, and an optical filter device formed on a passivation layer and deposited over the photodiode device, the optical filter device having a first plurality of layers of a conducting material, a second plurality of layers of a dielectric material, wherein the first plurality of layers and the second plurality of layers stacked alternatingly, and wherein the optical filter device is configured to match at least a portion of the erythemal curve, resulting in the photocurrent generated by the photodiode device being a representation of a UV index.

Aspects of the present disclosure includes a method of manufacturing a sensor device including depositing a semiconductor layer on a dielectric layer to form a substrate, implanting a first plurality of ions into the semiconductor layer to form a first plurality of contacts of a plurality of photodiodes, implanting a second plurality of ions into the semiconductor layer to form a second plurality of contacts of the plurality of photodiodes, depositing a plurality of metal layers to form a plurality of contacts for the plurality of photodiodes, depositing a planarize dielectric layer over the plurality of photodiodes, and alternatingly depositing each of a first plurality of filter materials and each of a second plurality of filter materials over the planarize dielectric layer to form an optical filter that covers the plurality of photodiodes, the optical filter being configured to match at least a portion of the erythemal curve.

### BRIEF DESCRIPTION OF THE DRAWINGS

The accompanying drawings form part of the disclosure and are incorporated into the subject specification. The drawings illustrate example aspects of the disclosure and, in conjunction with the following detailed description, serve to explain at least in part various principles, features, or aspects of the disclosure. Some aspects of the disclosure are described more fully below with reference to the accompanying drawings. However, various aspects of the disclosure can be implemented in many different forms and should not be construed as limited to the implementations set forth herein. Like numbers refer to like elements throughout.

FIG. 1 is a chart that presents irradiance as a function of wavelength in the UV portion of the electromagnetic (EM) radiation spectrum, including a trace indicative of erythemal curve, another trace indicative of sunlight spectrum, and yet another trace indicative of effective spectrum, according to various aspects of the present disclosure.

FIG. 2 is a chart that presents performance of example UV sensor devices and existing instruments as a function of wavelength in the UV portion of the electromagnetic radiation spectrum according to various aspects of the present disclosure.

FIG. 3A is a block diagram that illustrates a cross-section of an example sensor device, in accordance with one or more aspects of this disclosure.

FIG. 3B is table that presents the structural parameters of the example UV sensor device shown in FIG. 3A according to various aspects of the present disclosure.

FIG. 4 is a chart that presents performance of example sensor devices and an example instrument, and also presents performance of an example UV sensor device in accordance with aspects of this disclosure as a function of wavelength in the UV portion of the electromagnetic (EM) radiation spectrum.

FIG. 5 is a chart that presents scatter plots of determined/calculated UV index using the corresponding device versus true UV index according to various aspects of the present disclosure.

FIG. 6 is a chart that presents scatter plots of determined/calculated UV index versus true UV index for example UV sensor devices in accordance with aspects of this disclosure, with fabrication variations in consideration.

FIG. 7A is a chart that presents photocurrent-to-UVI linearity as a function of number of filter layers in a sensor device, in accordance with one or more aspects of this disclosure.

FIG. 7B is a chart that presents maximum responsivity for wavelengths less than 300 nm as a function of number of filter layers in a sensor device, in accordance with one or more aspects described herein.

FIG. 8A is a chart that presents total thickness of filter configuration as a function of number of optical filter layers in a sensor device, in accordance with one or more aspects described herein.

FIG. 8B is a chart that presents calculated UVI error (denoted by UVI difference) as a function of number of optical filter layers in a sensor device, in accordance with one or more aspects described herein.

FIGS. 9A-9Y are diagrams showing an example of a process to produce a UV sensor device with an example filter device, in accordance with one or more aspects of this disclosure.

FIG. 10 is a diagram showing an example of a method for manufacturing a UV sensor device according to aspects of the present disclosure.

### DETAILED DESCRIPTION

Embodiments of this disclosure may address, among other technical challenges, the issue of existing chipset-scale UV index (UVI) sensor devices not being accurate due to the optical filter devices present in those devices not being sufficiently close to the erythemal action spectrum (the “erythemal curve”). The erythemal action spectrum is a weighting function that is used to calculate sunburn redness. Specifically, the erythemal spectrum relates to the UV index. Integration of the resulting effective sunlight spectrum and the erythemal action spectrum divided by 25 mW/m² defines the UV index:

$$UVI = \frac{\int ery ( λ ) \times {I}_{Sun} ( λ ) d λ}{{25}^{mW} / {m}^{2}} \qquad Eq . ( 1 )$$

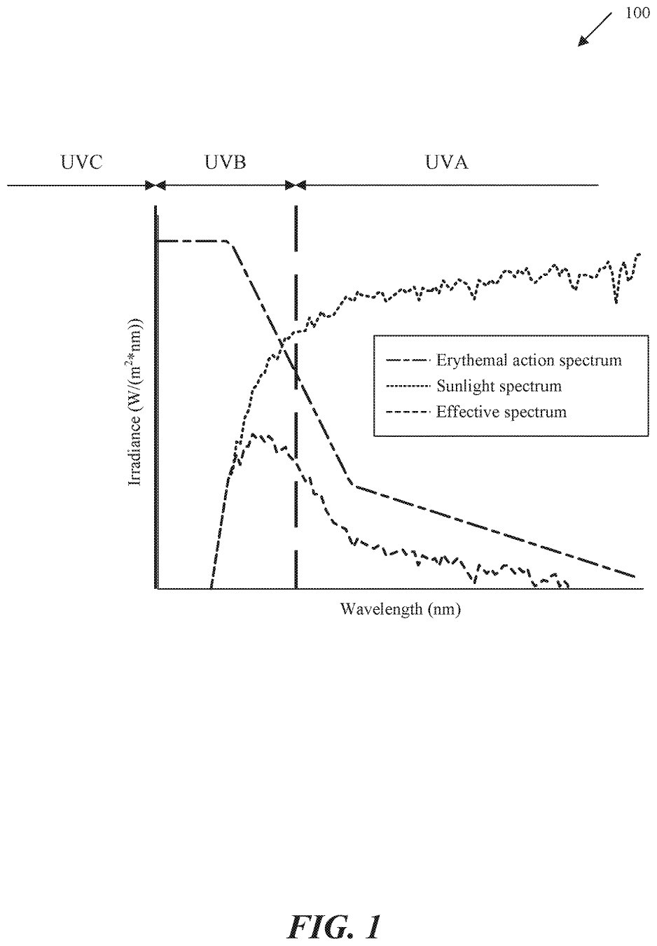

In Eq. (1), ery(λ) and I_{Sun}(λ) represent, respectively, the erythemal action spectrum and the sunlight spectrum. As an illustration, FIG. 1 is a chart 100 that presents irradiance as a function of wavelength in the UV portion of the electromagnetic (EM) radiation spectrum, including a trace indicative of the erythemal curve, another trace indicative of sunlight spectrum, and yet another trace indicative of effective spectrum, which is the product of erythemal curve and sunlight spectrum.

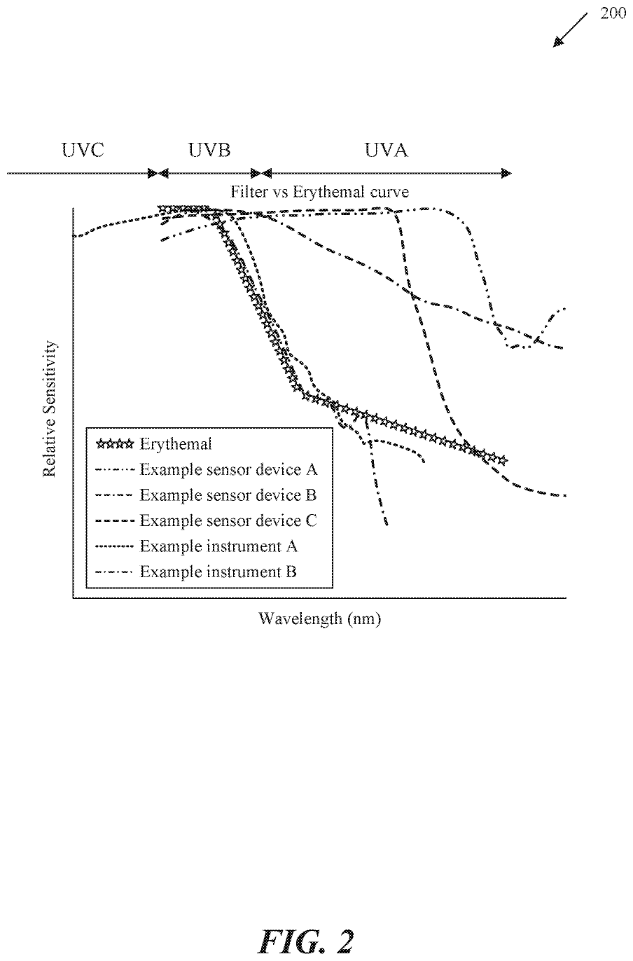

Further, to illustrate the issue mentioned above, FIG. 2 is a chart 200 that presents relative sensitivity of optical filters present in existing chipset-scale UV sensor devices and instruments as a function of wavelength in the UV portion of the electromagnetic radiation spectrum. The chart 200 also presents the erythemal curve. Although Instrument A and Instrument B match the erythemal mostly satisfactorily, Instrument A and Instrument B are each about two orders of magnitude more costly than each one of Sensor Devices A to C. Such a tradeoff between performance and cost may not be adequate or desired for prevalent deployment in the field.

To address the issue mentioned above, among other technical issues, embodiments of the technologies described herein, individually or in combination, provide UV sensor devices that include optical filter devices that essentially match (e.g., more than 80%, 85%, 90%, 95%, 99% or other percentage) the erythemal curve and provide a photocurrent that varies linearly with the integrated solar spectrum under the erythemal weight curve. Thus, such UV sensor devices provide photocurrent and, therefore, a calculated UV index that is directly proportional to a true UV index (UVI) with the use of a fixed calibration constant. The UV sensor devices can be formed, in some implementations, using a combination of a silicon-on-insulator (SOI) substrate having a device layer thickness of about 1 μm. Other SOI substrate with different device layer thicknesses may also be implemented according to various aspects of the present disclosure.

Embodiments of the technologies described herein, individually or in combination, provide optical filter devices that can eliminate the need of additional calibrations using prohibitively large amounts of information, such as geography location, time, date, altitude, and the like. As a results, embodiments of the technologies described herein, individually or in combination, can simplify detection and determination of UV indices.

UV sensor devices in accordance with this disclosure may include a photodiode integrated into a photonic cavity that includes an absorption region on a silicon on insulator (SOI) wafer to reduce long wavelength absorption (e.g., NIR absorption), and a multilayer dielectric optical filter device that is formed to spectrally attenuate the incoming light at a rate proportional to the erythemal weighting curve when combined with the photodiode spectral responsivity curve.

The optical filter devices that are part of the UV sensor devices according to aspects of this disclosure may maintain average transmission greater than 1.5% yielding approximately 100 pA per UVI per mm² in some particular fabrication variation combinations, which can be detected by typical analog front end (AFE) circuitry. Other values may also be possible.

The UV sensor devices in accordance with aspects of this disclosure are robust to thickness variation of layers that form the optical filter devices integrated in those UV sensor devices. The accuracy may be within ±0.35 UVI with min-max variation of 4.4% in some cases. Other UVI values and/or variations are also possible.

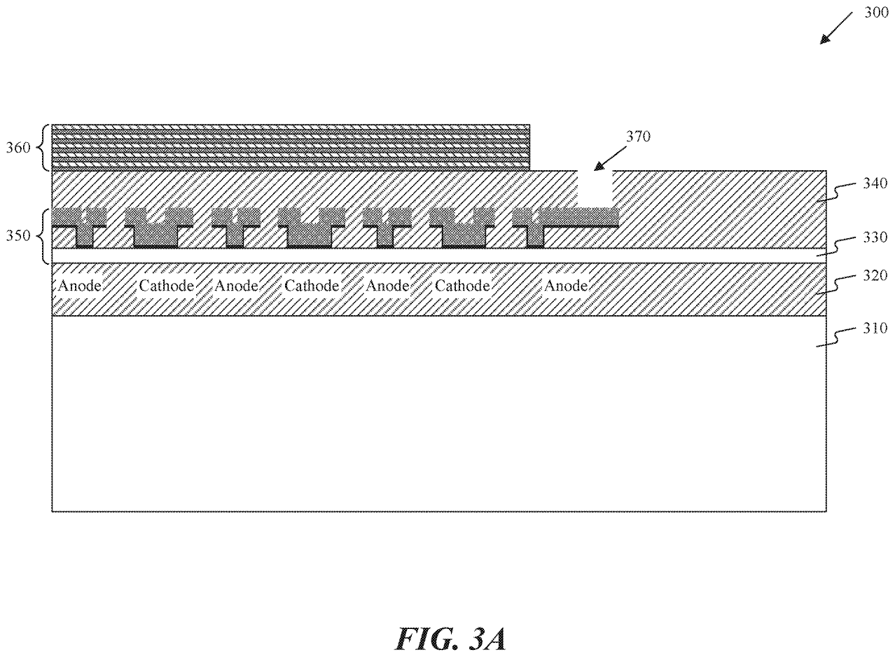

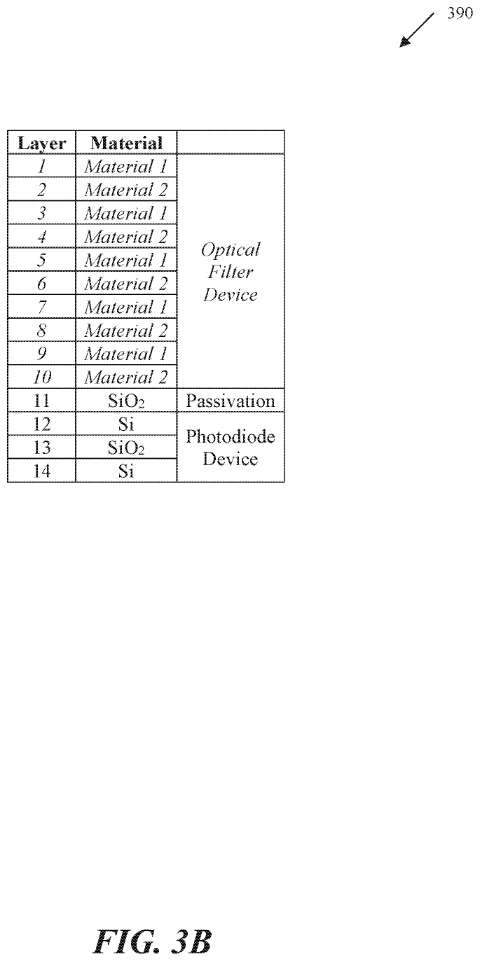

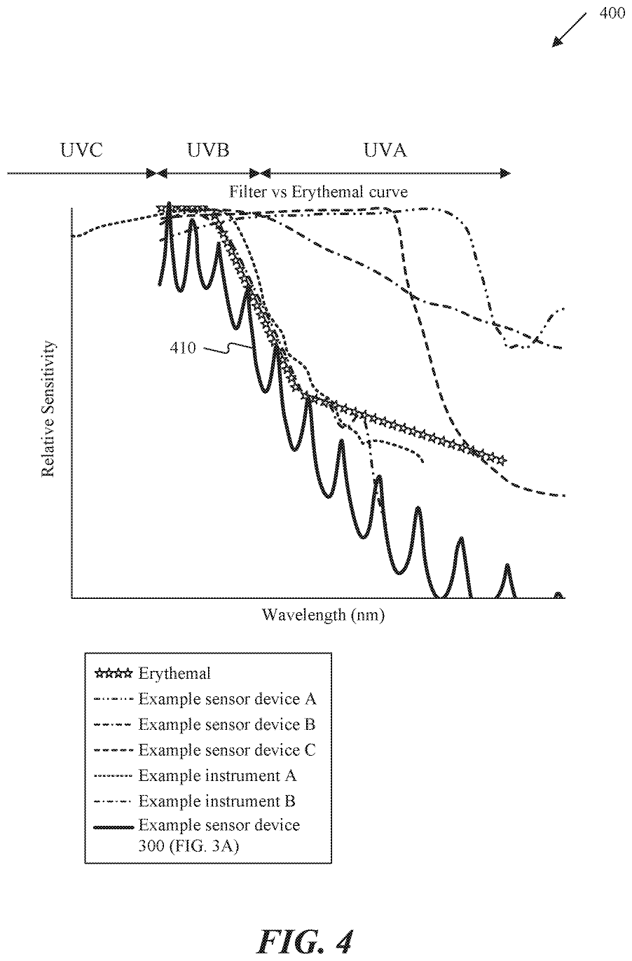

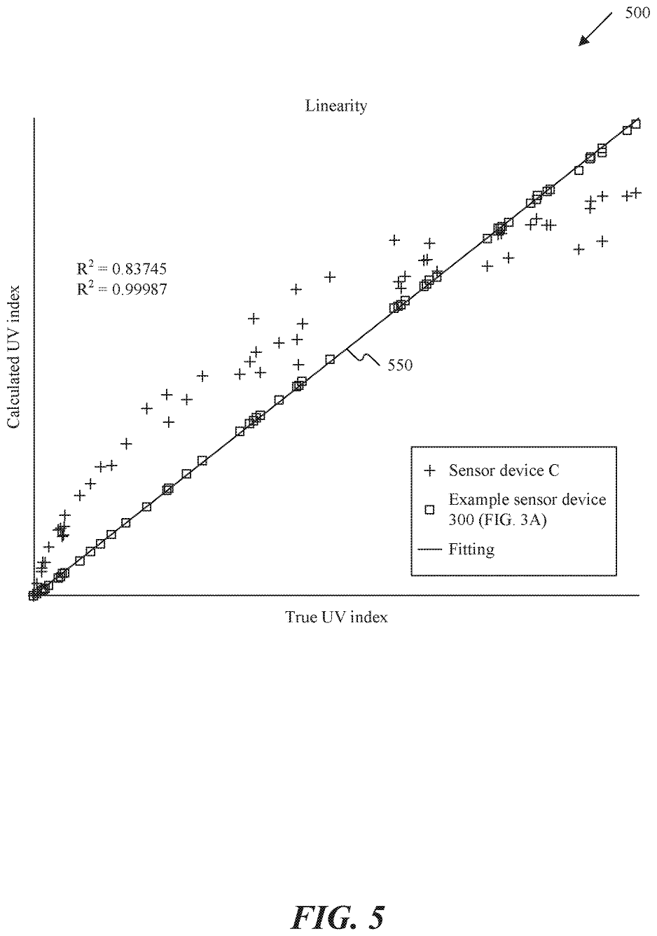

FIG. 3A is a block diagram that illustrates a cross section of an example of a UV sensor device, in accordance with one or more aspects of this disclosure. The example UV sensor device 300 is a monolithic device that is formed on a silicon-on-insulator (SOI) wafer that includes a silicon substrate 310 (or a “handle”), a silicon dioxide layer 320 that is a buried oxide layer, a silicon layer 330 (referred to as a “device layer”), and/or a passivation layer 340. The example UV sensor device 300 also includes a photodiode device 350 and an optical filter device 360. The optical filter device 360 includes multiple layers of alternating materials, such as HfO₂ and aluminum. Other dielectric materials with very low UV absorption (e.g., SiO₂, Al₂O₃) and/or other metals that exhibit surface plasmon resonance in the UV (e.g., Ga, Mg, Rh) may be used to form the optical filter device 360. The example UV sensor device 300 also includes an exposed electrode 370 that serves as an anode or a cathode. In some aspects, the dielectric materials and/or metals may each have a UV absorption value lower than a threshold value.

FIG. 3B is table 390 that presents the structural parameters of the example UV sensor device 300 shown in FIG. 3A. The filter device 360 has multiple layers (e.g., 5-layer, 10-layer, 15-layer, or other number of layers) stack of alternating HfO₂ layers and Al layers. As indicated above, other combination of alternating materials may also be used according to various aspects of the present disclosure. Fabricated optical filter coating may be within a predetermined, or otherwise desired, min-to-max of target thickness. In some cases, the min-to-max variation may be ±2% which is well approximated by standard deviation of 0.5% on each layer in the HfO₂/Al stack. A min-to-max variation of +2% represents a typical semiconductor manufacturing/processing constraint. In other cases, the min-to-max variation may be ±3%. The disclosure is, of course, not limited to such cases and fabricated optical filter coatings may be within other min-to-max variation of a target thickness while achieving a desired performance. The device layer (silicon layer 330 in FIG. 3A) has a thickness of about 300 nm. The silicon dioxide layer 320 has a thickness of about 1 μm. The thickness variation of the passivation layer 340 (shown as “Passivation” in the table 390) corresponds to the typical value achievable in semiconductor manufacturing/processing. The SOI substrate thickness variation corresponds to specification provided by a manufacturer. Other layers and/or thicknesses of the layers may also be used according to various aspects of the present disclosure.

In an aspect of present disclosure, the UV sensor device 300 includes an edge protection structure to block coupled light in the silicon layer 330. For example, the edge protection structure may include a metal trench surrounding at least a portion of the photodiode device 350. Other edge protection structure may also be implemented.

FIG. 4 is a chart 400 that presents performance over wavelengths in the UV portion of the EM radiation spectrum for existing UV sensor devices and instruments and for the example UV sensor device 300 (FIG. 3A) in accordance with aspects of this disclosure. Performance is represented by relative sensitivity. The existing UV sensor devices and instruments are the same as those referred to in connection with FIG. 2. Trace 410 in the chart 400 corresponds to the performance of the example UV sensor device 300. As it can be gleaned from the trace 410, the example UV sensor device 300 matches the erythemal curve well. The ripples in the trace 410 are the Fabry-Perot interference pattern originating in the 3 μm SiO₂ passivation layer 340 (FIG. 3A) present in the example UV sensor device 300. The interference pattern does not deteriorate the optical filter performance. Other UV sensor devices in accordance with aspects of this disclosure present similar performance as that of the example UV sensor device 300.

FIG. 5 is a chart 500 that presents a first scatter plot (crosses) of determined/calculated UV index versus true UV index for an existing UV sensor device (Sensor Device C; see FIG. 2), and a second scatter plot (squares) also of the determined/calculated UV index versus true UV index for the example UV sensor device 300 (FIG. 3A and FIG. 3B) described herein. The chart 500 represents performance of the example UV sensor device 300. The chart 500 also includes a line 550 corresponding to a linear fit to the data in the scatter plot for such an example UV sensor device. The linear fit yields a coefficient of determination R² that is equal to 0.99987. As mentioned, if an optical filter device matches the erythemal curve well, the photocurrent and, thus, calculated UV index can be linear with the true UV index. From chart 500, it can be readily concluded that the example UV sensor device 300 has superior performance relative to the existing UV sensor device (Sensor Device C), which has a lower coefficient of determination (e.g., 0.083745). The coefficients of determination above are shown as an example and other values may also be possible.

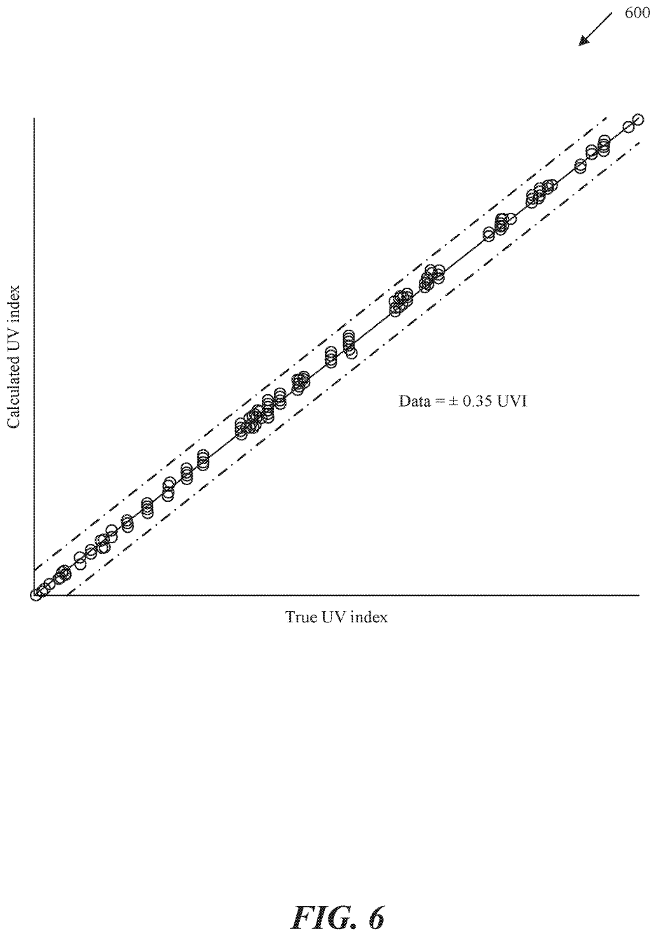

FIG. 6 is a chart 600 that presents scatter plots of the determined/calculated UV index versus the true UV index for example UV sensor devices in accordance with aspects of this disclosure. The example UV sensor devices are variants of the example UV sensor device 300 (FIG. 3A and FIG. 3B) where thickness of filter layers have been varied according to a min-max variation of 4.4% and also includes variation in the photodiode device. From the results shown in the chart 600, it can be concluded that UV sensor device accuracy can be within ±0.35 UVI when filter thickness variation is incorporated. The min-max variation of 4.4% adequately represents thickness variation arising from a process based on plasma deposition for fabrication of the optical filter layers of the UV sensor devices in accordance with aspects of this disclosure. The numbers for the variation and/or the UVI are shown as examples and other numbers may also be possible according to various aspects of the present disclosure.

Embodiments of the technologies in accordance with this disclosure are not limited to the example UV sensor device 300 shown in FIG. 3A and/or having the structure summarized in FIG. 3B. Indeed, there are several sensor devices in accordance with this disclosure that include other arrangements of HfO₂/Al pairs and satisfy the performance condition that photocurrent be linearly proportional to UV Index (that is, R²=1). Of the many available UV sensor devices, some devices may be more suitable than other devices. Specifically, a suitable UV sensor device having a HfO₂/Al multilayer optical filter matches the erythemal curve and has a high transmission at wavelengths less than 300 nm in order to permit satisfactory photodiode responsivity. In other words, a suitable UV sensor device matches the erythemal curve and passes enough light to provide a usable photocurrent (e.g., readily measurable photocurrent.)

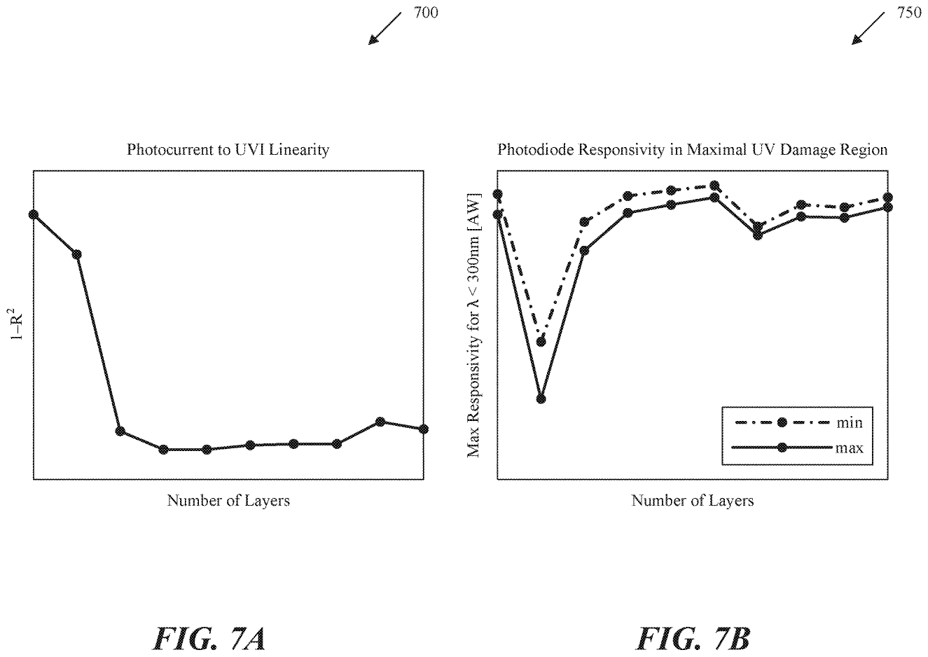

FIG. 7A is a chart 700 that presents photocurrent-to-UVI linearity, represented by 1−R², as a function of number N of filter layers, from a single HfO₂/Al pair of layers (n=2) to 10. HfO₂/Al pairs of layers (N=20), in accordance with one or more aspects of this disclosure. Filter configurations/arrangements having six or more layers yield a value of 1−R² that are less than 0.1, 0.05, 0.01, 0.005, 0.001, or other values. Thus, those configurations may provide satisfactory photocurrent-to-UVI linearity.

As mentioned, satisfactory linearity between photocurrent and UVI may not be sufficient to provide a usable UV sensor device in accordance with aspects of this disclosure. Generation of a usable photocurrent is desired. FIG. 7B is a chart 750 that includes two traces, each presenting maximum responsivity for wavelengths less than 300 nm as a function of number N of filter layers.

From both the chart 700 and the chart 750, it may be concluded that suitable UV sensor devices in accordance with aspects of this disclosure may include 4, 5, 6, 7, or 8 pairs of HfO₂/Al layers—that is, 8, 10, 12, 14, or 16 filter layers—in the optical filter device that is part of the UV sensor device. In some cases, a UV sensor device having 9 or 10 pairs of HfO₂/Al layers may be optionally provided as suitable devices. As is described herein, FIG. 3A and FIG. 3B illustrate an example filter device 300 having N=10 layers. Other types and/or numbers of filter layers may also be used according to various aspects of the present disclosure.

It is noted that increasing thickness of a filter configuration, e.g., number of layers, increases fabrication cost. Accordingly, it may be desirable to minimize calculated UV Index error for fabrication variation. Filter layers may not have a defined/specific thickness-fabrication process leads to variation in the thickness, but the variation may be controlled to within less than 5% of a desired/defined thickness. A filter device and a system including the filter device are desired to be robust against such thickness variation.

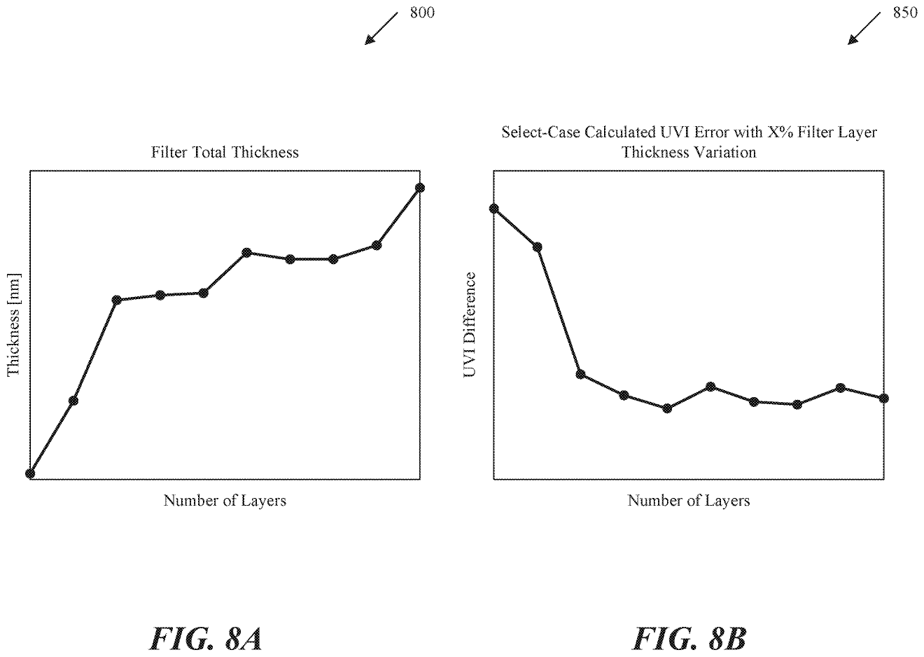

FIG. 8A is a chart 800 that presents total thickness of filter configuration as a function of number of filter layers.

FIG. 8B is a chart 850 that presents calculated UVI error (denoted by UVI difference) as a function of number of filter layers. The maximum UVI difference is calculated when a certain % thickness variation (e.g., 1%, 3%, 4%, 5%, 7%, 10%, etc.) is considered in each filter layer of a filter device in accordance with aspects of this disclosure. Without intending to be bound by theory and/or modeling, UV sensor devices according to aspects of this disclosure may be fabricated to have HfO₂/Al filter stacks with even pairs, with layer thickness less than 2/2n and greater than λ/8n, in order to provide usable devices to measure UVI reliably. Here, A is a characteristic wavelength of a filter stack/configuration and n is the magnitude of the refractive index for HfO₂ and Al at that characteristic wavelength (approximately 2.08 for HfO₂ and 3.37 for Al). In the example filter device 300, λ may be equal to 280 nm. It is noted that typically, for a passband filter, the characteristic wavelength λ may be the midpoint wavelength of the passband region where transmission is to be maximized. In other cases, such as a low pass filter, the characteristic wavelength λ may be the shortest wavelength of the low pass filter where transmission is to be maximized. The erythemal curve is similar in shape to a low pass filter. In addition, or in some cases, the filter devices can have HfO₂ layer thickness between about 15 nm and 68 nm, and Al layer thickness between 10 nm and 31 nm. Other thicknesses may also be used. The thickness of a layer that forms a filter stack can have a defined variation which can be quantified in terms of a standard deviation. For instance, as is shown in table 390 (FIG. 3B), each layer in a filter stack can be a same variation, e.g., 0.5% standard deviation. Further, the filter devices can have a UV index accuracy of +0.35, which is superior to existing, substantially more expensive instruments to measure UV index.

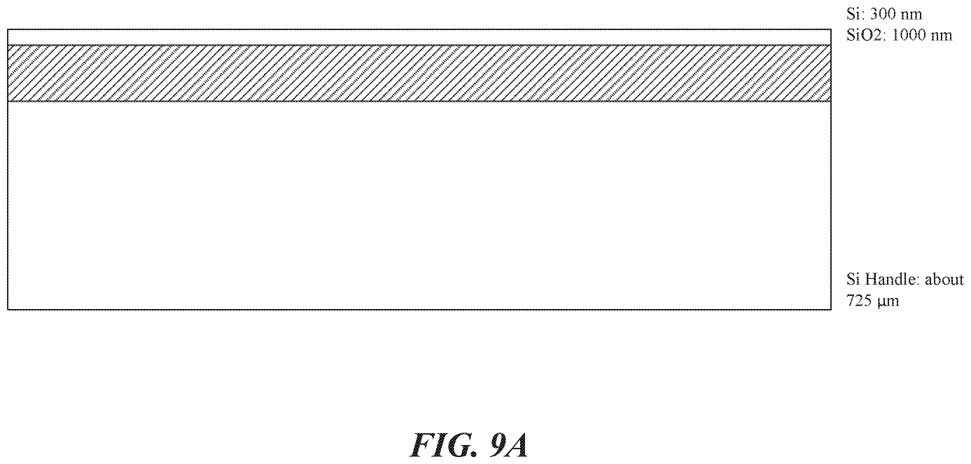

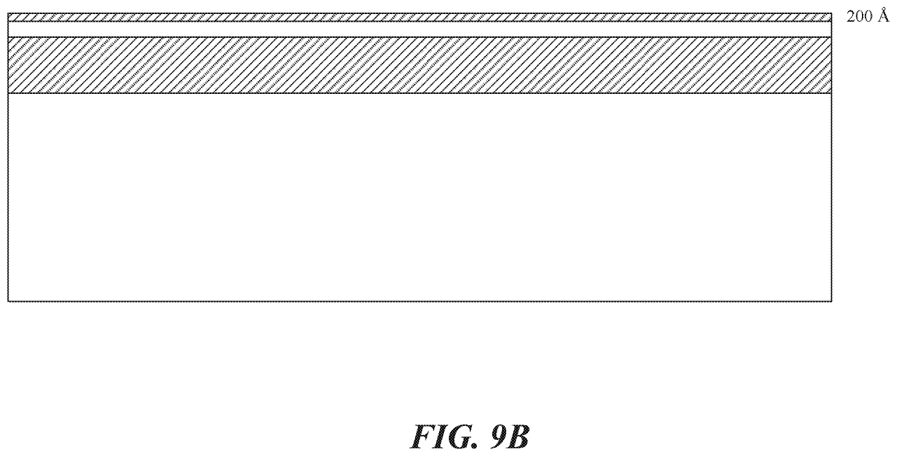

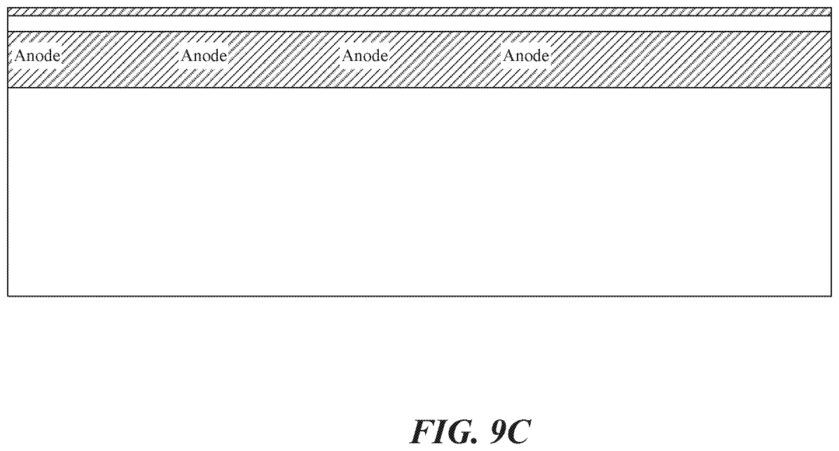

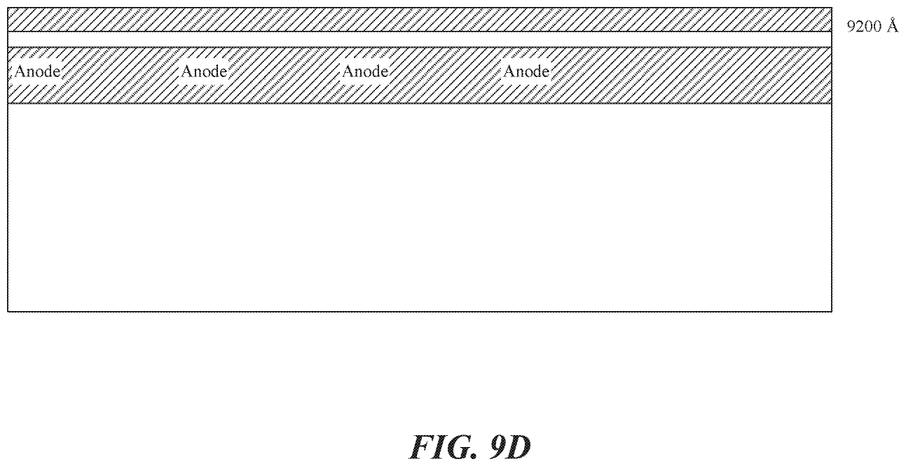

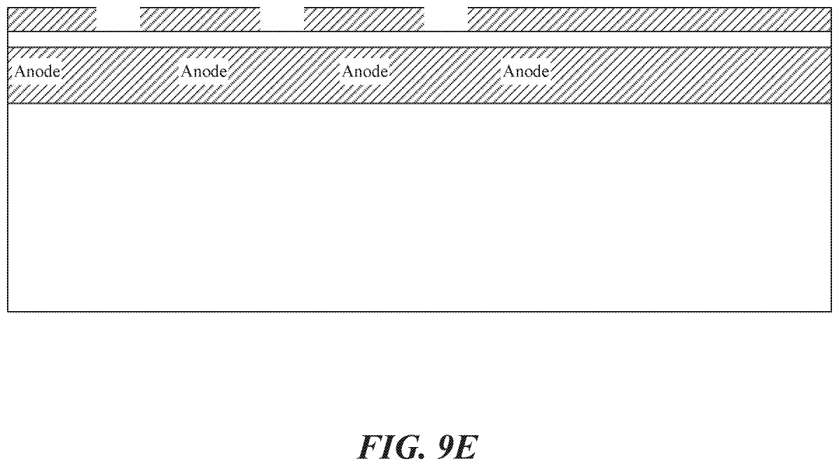

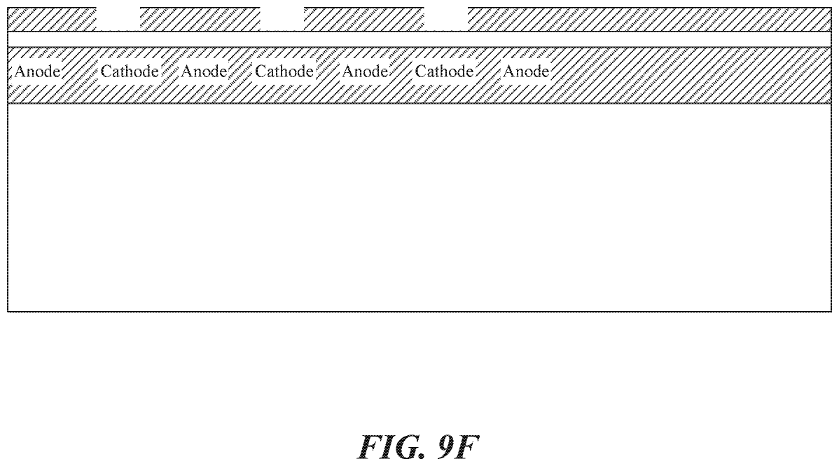

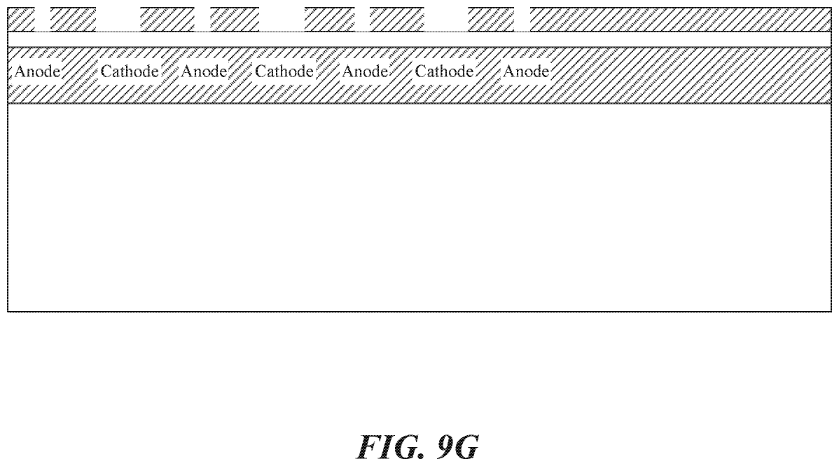

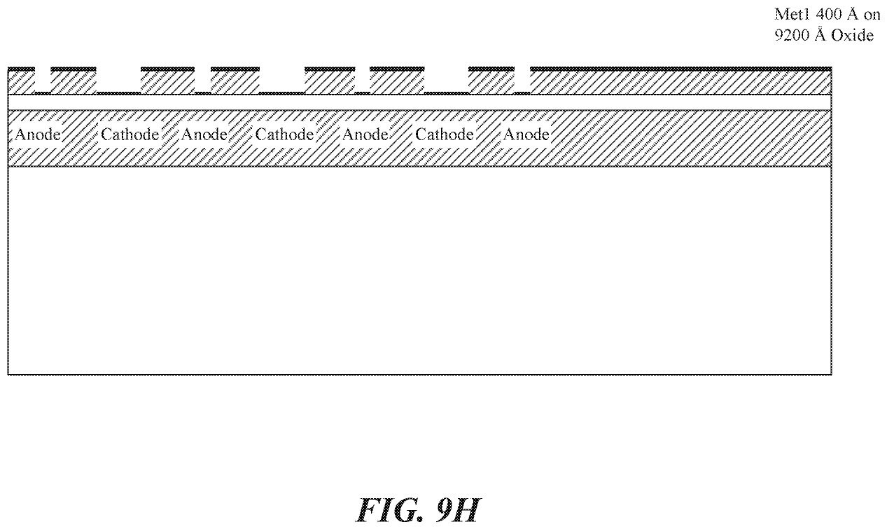

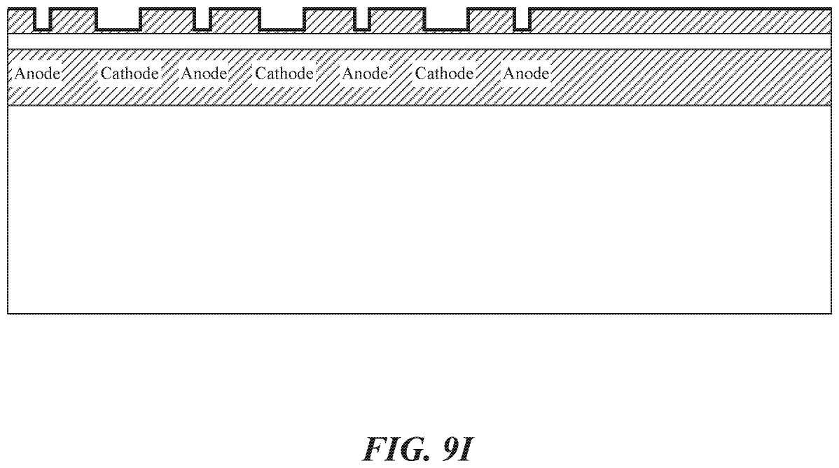

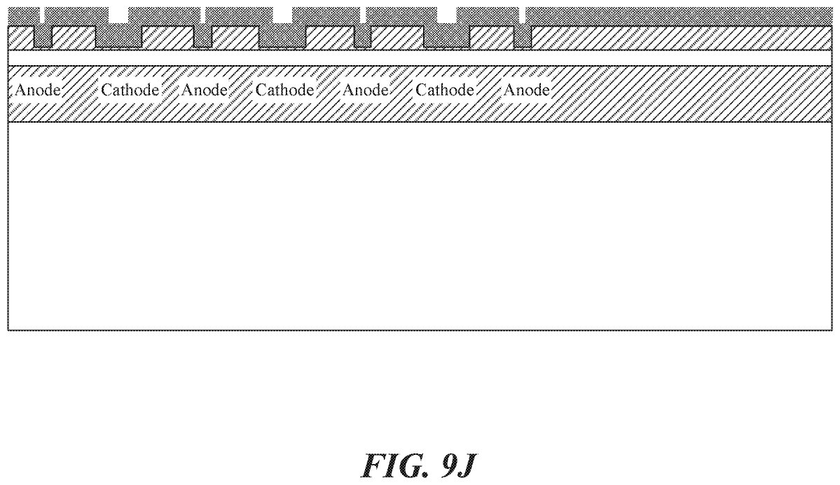

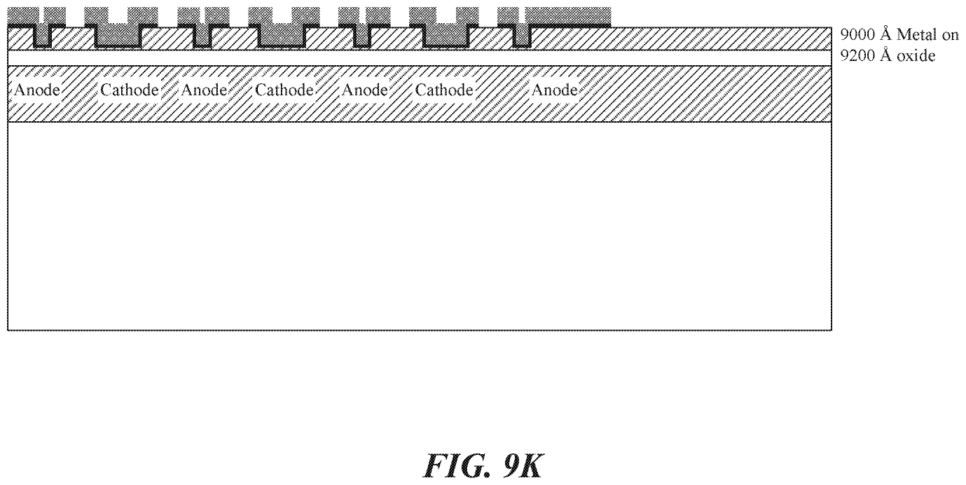

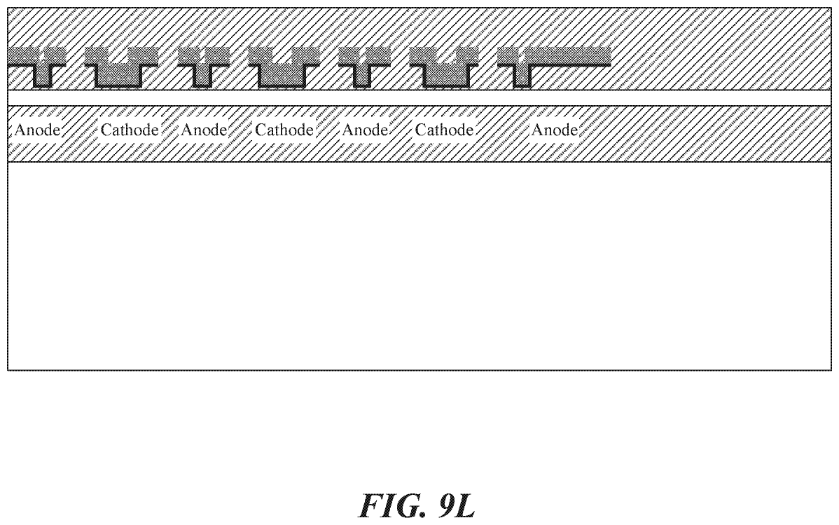

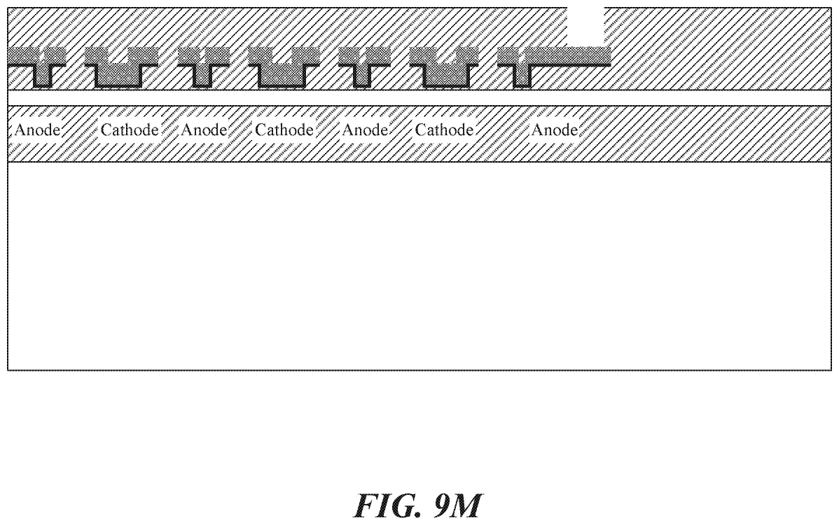

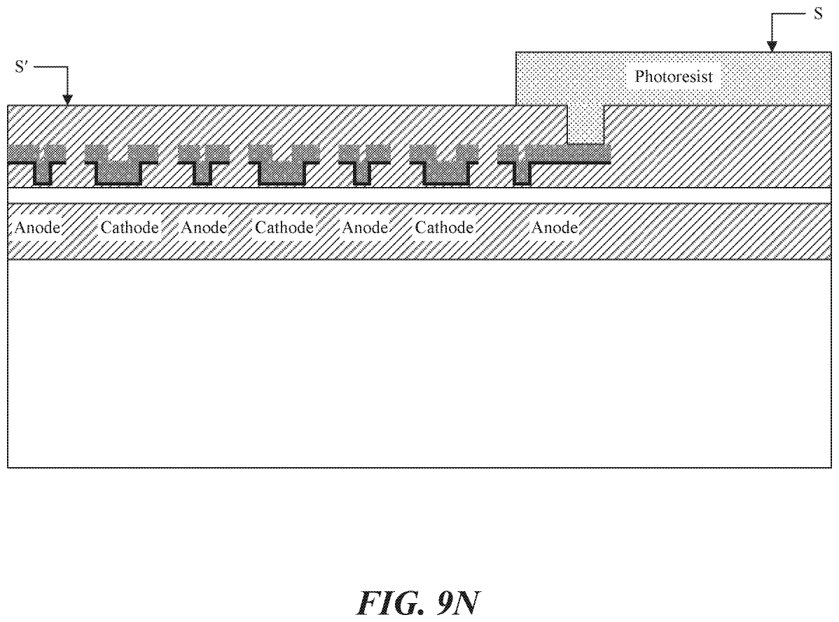

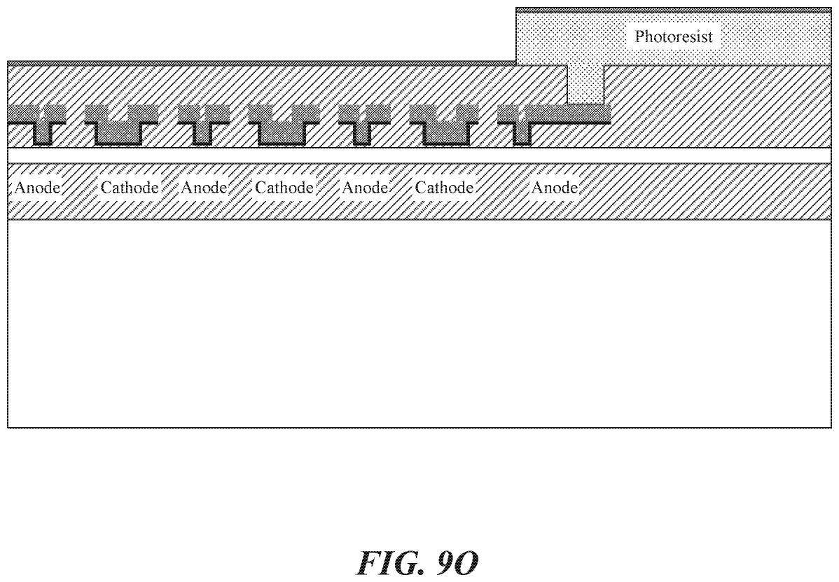

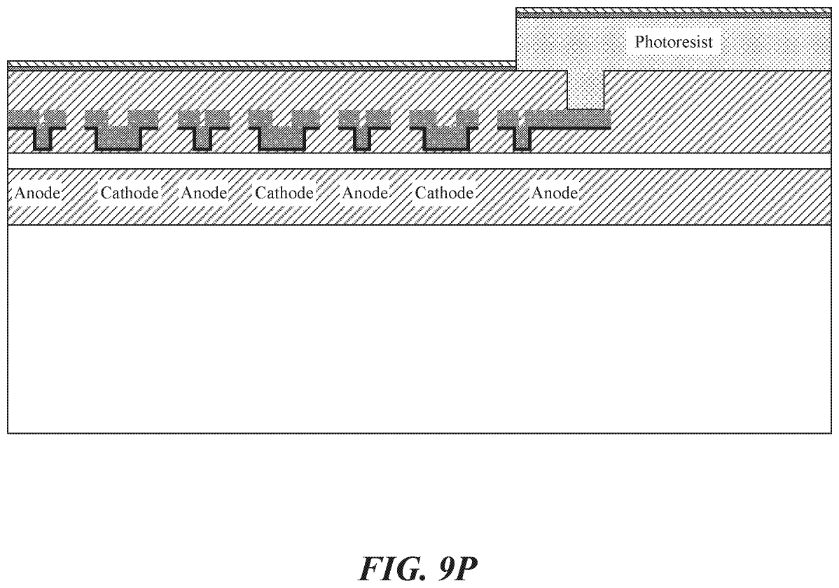

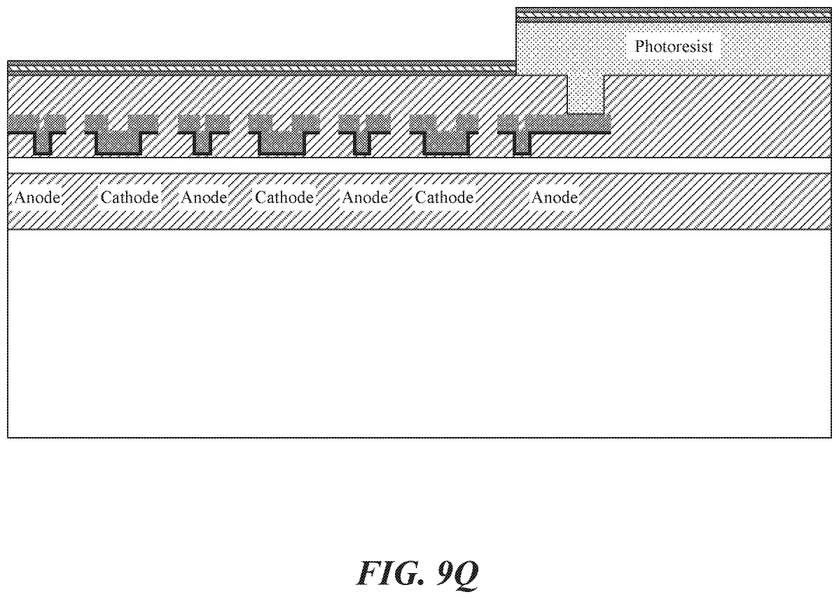

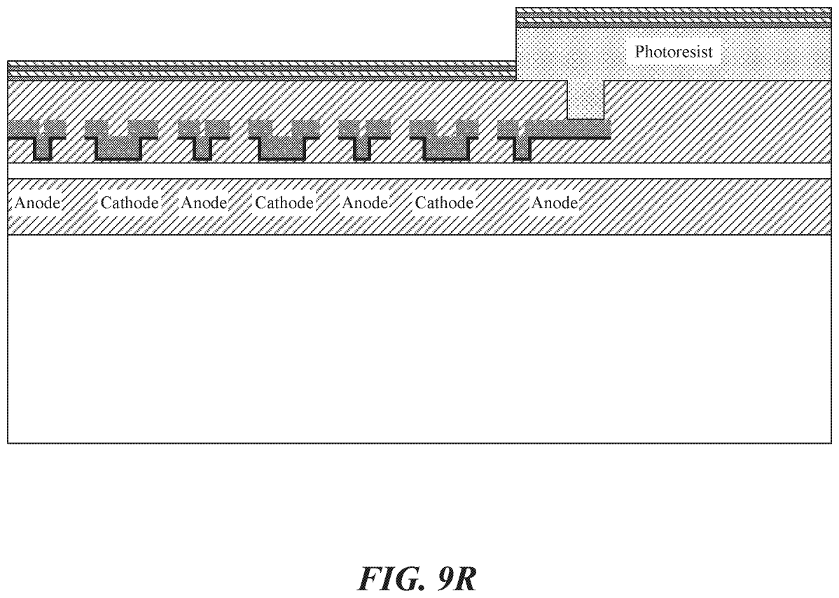

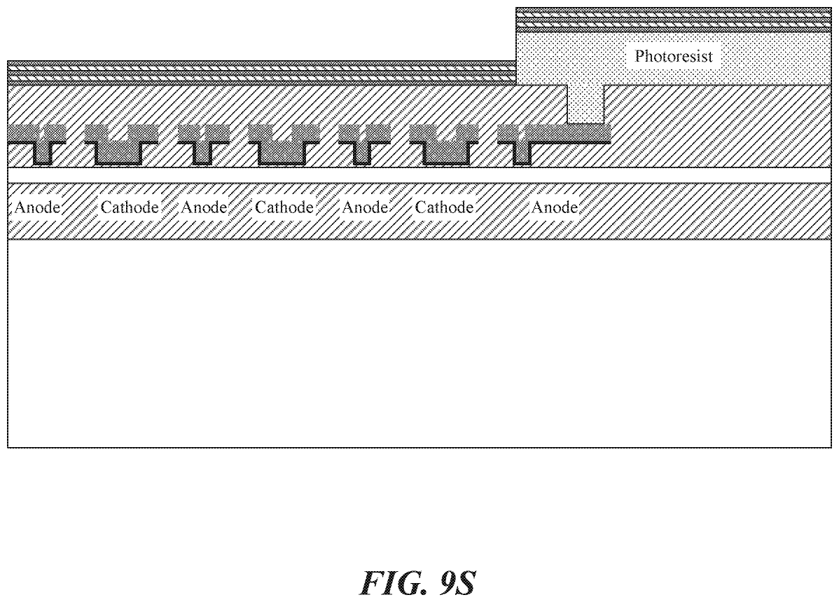

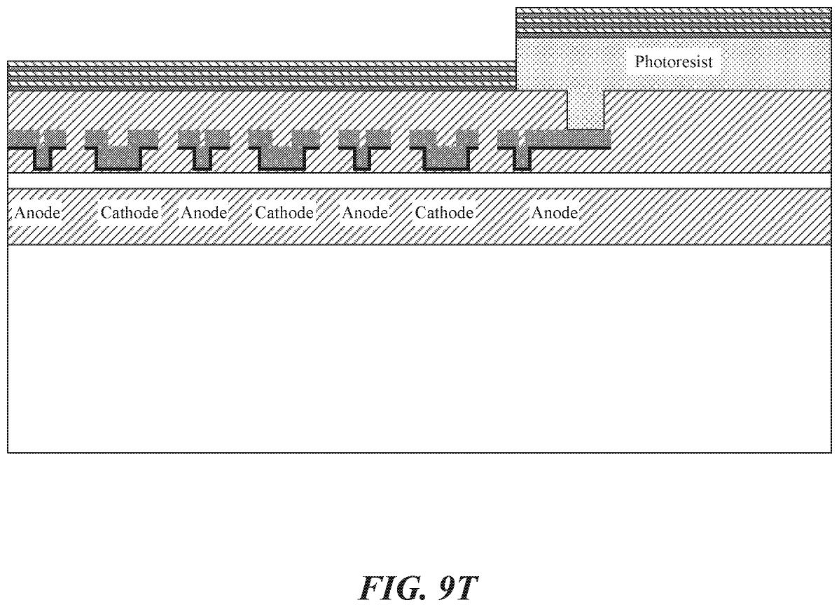

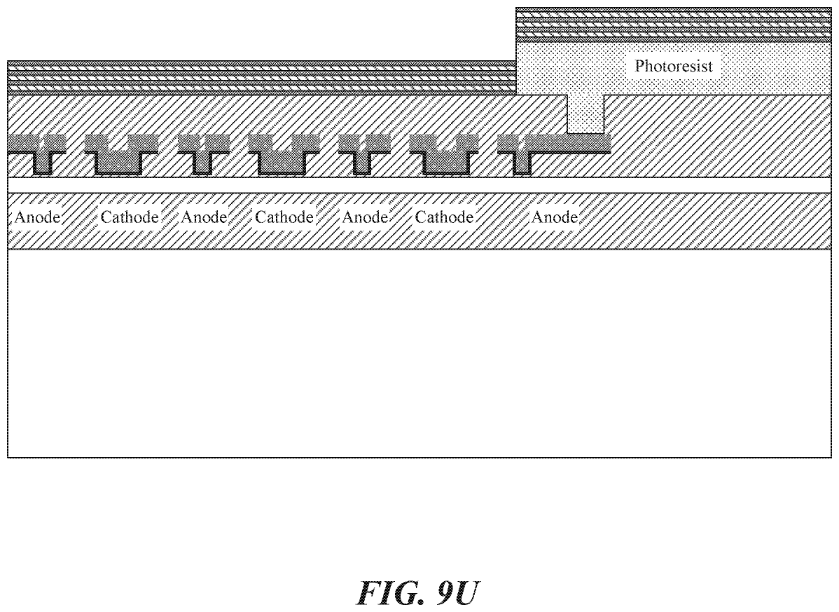

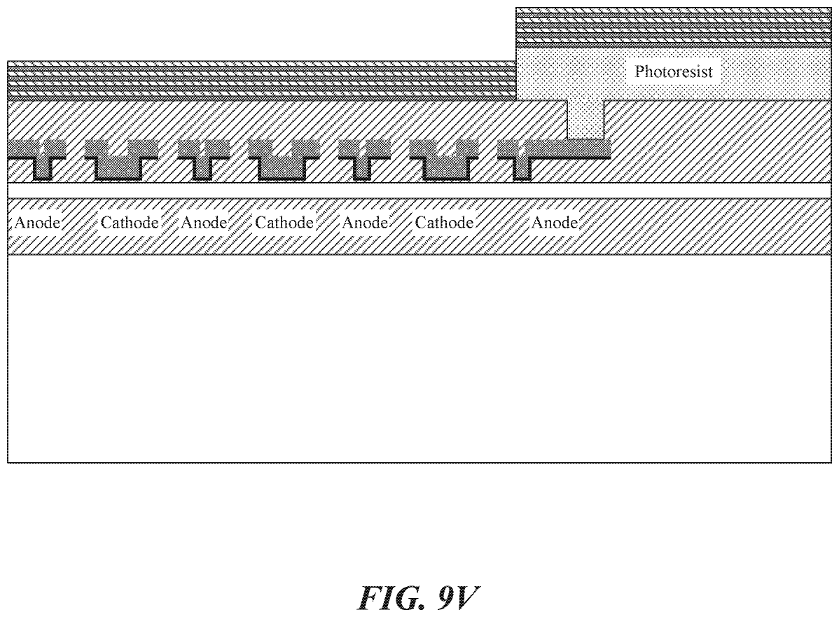

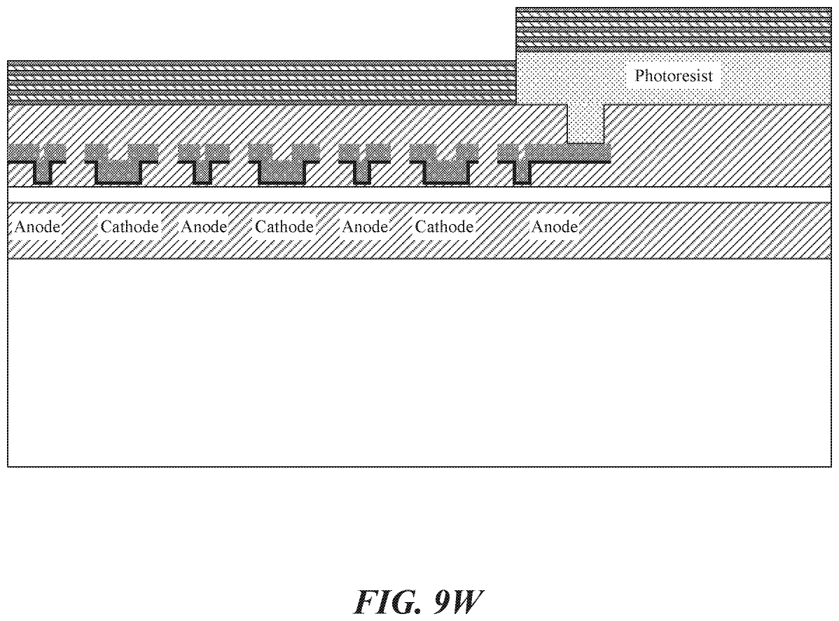

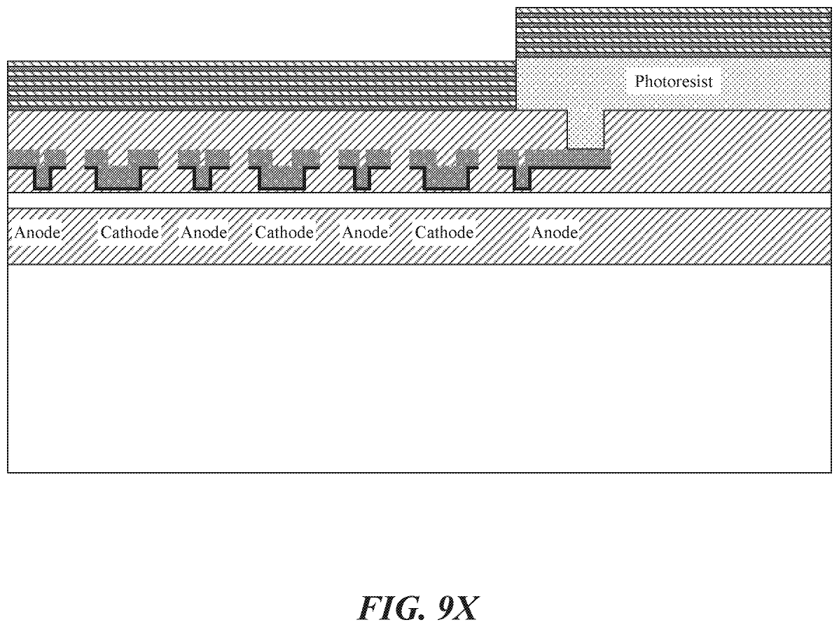

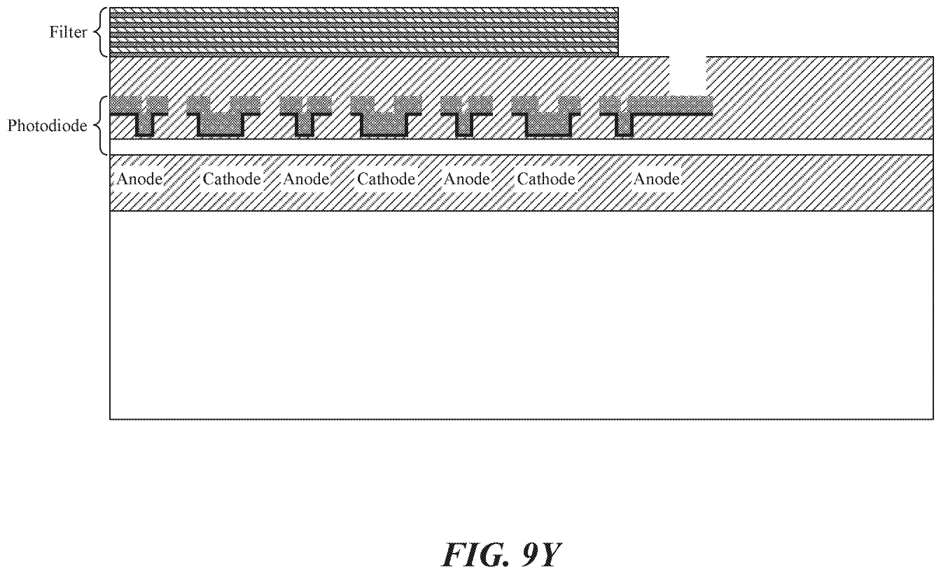

FIGS. 9A-9 show an example of a process to produce an example UV sensor device, in accordance with one or more aspects of this disclosure. The example process may be implemented by using plasma deposition (PD) for material deposition and ion implantation. One or more other techniques, individually or in combination with PD, may be used. Although the example process is illustrated with reference to the structure of the example UV sensor device 300 (see table 390 (FIG. 3B), the example process is not limited in that respect and can be implemented to form UV sensor devices having other types of optical filter devices with different arrangements of dielectric/metal layers. The example process shown herein is for illustration only, and different materials, thicknesses, and/or fabrication techniques may also be used according to aspects of the present disclosure.

As is shown in FIG. 9A, the example process may start by providing a SOI wafer including a silicon substrate (or “handle”) having a thickness of about 725 μm. The SOI wafer also includes a layer of SiO₂ having a thickness of about 1000 nm and a silicon device layer overlaying the layer of SiO₂ and having a thickness of approximately 300 nm. It is noted that the thickness of the layer of SiO₂ and/or the thickness of the silicon device layer may be different in some implementations.

Further, as is shown in FIG. 9B, a layer of a silicon dioxide is thermally grown on the surface of the silicon device layer that is part of the SOI wafer. A chemical vapor deposition (CVD) chamber, a physical vapor deposition (PVD) chamber, an atomic layer deposition (ALD) chamber, or other manufacturing equipment may be used to grow and/or deposit the silicon dioxide.

Further, as is shown in FIG. 9C, p-type ions (e.g., B, BF₂) are implanted in multiple first regions of the silicon device layer that overlays the layer of SiO₂. The multiple implanted regions form respective p-type anodes (collectively referred to as “the p-type anode”). An ion implanter may be used to implant the p-type ions.

Further, as is shown in FIG. 9D, another layer of silicon dioxide is deposited on the screen layer of silicon dioxide, yielding another layer of silicon dioxide having a thickness of about 9200 Å. A CVD chamber, a PVD chamber, and/or an ALD chamber may be used to deposit the silicon dioxide.

Further, as is shown in FIG. 9E, multiple regions of the silicon dioxide layer are etched or otherwise removed to form a mask to for n-type ion implantation. Here, a layer of photoresist is deposited (e.g., using spin deposition and/or spray deposition) on the silicon dioxide layer. A photomask is used to define the patterns on the photoresist. The photoresist is developed to generate the patterns. After the generation of the patterns on the photoresist, a reactive ion etcher (RIE) is used to etch the silicon dioxide layer to form the mask for the n-type ion implantation.

Further, as is shown in FIG. 9F, n-type ions (e.g., P, As, Sb) are implanted in multiple second regions of the silicon device layer that overlays the layer of SiO₂. The multiple second regions are interspersed between the multiple first regions, with each one of the multiple second regions being adjacent to two of the multiple first regions. The multiple second implanted regions form respective n-type cathodes (collectively referred to as “the n-type cathode”). An ion implanter is used to implant the n-type ions.

The example process includes a stage to form contacts. Further, as is shown in FIG. 9G, a mask is formed on the layer of silicon dioxide by etching or otherwise removing third regions of the layer of silicon dioxide. Each region of the multiple third regions exposing a surface of a p-type implanted anode region. A RIE etches the layer of silicon dioxide.

As is shown in FIG. 9H, the mask is used to deposit a layer of platinum (or another similarly conducting metal, such as a noble metal) over each of the exposed surfaces of the p-type implanted anode regions and n-type cathode regions. Each layer of platinum may have a thickness of about 400 Å. The multiple layers of platinum may be sputtered or evaporated and sintered. After deposition of the layers of platinum, the mask exposes those layers. A sputterer, an evaporator, a CVD chamber, a PVD chamber, or other equipment may be used to deposit the platinum.

As part of forming the contact, the example process includes the deposition of a metal or another type of conductor (either one generically referred to as “Metal,” for the sake of nomenclature). To that end, as is shown in FIG. 9I, the mask exposing the layers of platinum is coated with a layer of barrier metal (e.g., TiW or TiN). The layer of barrier metal maintains the recess structure of the mask. A sputterer, an evaporator, a CVD chamber, a PVD chamber, or other equipment may be used to deposit the barrier metal.

Then, as is shown in FIG. 9J, a layer of conductive metal (e.g. Al or AlCu) is deposited on the layer of barrier metal. The thickness of the layer of conductive metal is such that the recesses structure of the mask is fully covered, and other smaller recesses are formed. A thickness of the bilayer formed by the layer of barrier metal and the layer of conductive metal may be about 9000 Å, for example. The inclusion of the barrier metal may not be required and, thus, may be omitted in some cases. A sputterer, an evaporator, a CVD chamber, a PVD chamber, or other equipment may be used to deposit the conductive metal.

In addition, as is shown in FIG. 9K, multiple regions of the bilayer metal stack are etched or otherwise removed to form a mask that exposes surfaces of silicon dioxide. Here, photolithography as described above and RIE are used to define the patterns for the bilayer metal stack.

As part of the example process, the structure depicted by the cross-section shown in FIG. 9L is planarized by depositing an additional layer of silicon dioxide. A CVD or PVD is used to deposit the silicon dioxide.

After planarization, as is shown in FIG. 9M, a region of the added layer of silicon dioxide is removed so as to expose a portion of the metal layer, thus creating a bond pad opening. A photolithography process as described above and a RIE are used to selectively expose the metal layer.

The example process also includes a filter deposition stage to form a multilayer optical filter in accordance with aspects described herein. To that end, as is shown in FIG. 9N, a layer of photoresist is deposited onto the layer of silicon dioxide added during planarization. The layer of photoresist is then patterned so as to expose a surface (denoted by S′ in FIG. 9N) of the layer of silicon dioxide. A surface (denoted by S in FIG. 9N) of the photoresist also is exposed. A photolithography process as described above is used to pattern the photoresist. An optional RIE and/or ashing process may be used to clean the surface prior to the lift off process.

Also to form the multilayer optical filter, as is shown in FIGS. 9O-9X, multiple layers of aluminum and HfO₂ are deposited alternatingly onto the structure depicted in FIG. 9N; that is, deposited onto S and S′. The nomenclature used to denote each of the deposited layers is consistent with the nomenclature used in FIG. 3B. Here, one or more of a CVD chamber, a PVD chamber, an ALD chamber, a sputterer, an evaporator, and/or other equipment may be used to deposit the multiple layer optical filter.

Back to referring to FIGS. 9O-9X, each one of the layers of aluminum that are deposited has a thickness of about 200 Å. Each one of the layers of HfO₂ that are deposited has a respective thickness, as is shown in FIGS. 9P, 9R, 9T, 9V, 9X.

The alternating deposition of the multiple layers of aluminum and HfO₂ results in the structure depicted by the cross-section shown in FIG. 9X. The example process also includes a liftoff stage where the layer of photoresist is removed. As a result, the example UV sensor device depicted by the cross-section shown in FIG. 9Y is formed. Such an example UV sensor device is the same as the example UV sensor device 300 depicted in FIG. 3A. The liftoff process may be performed using a wet etch (e.g., immersing the entire substrate into a solvent to remove the photoresist, along with the layers on top of the photoresist) and/or a dry etch process using a RIE (e.g., oxygen plasma).

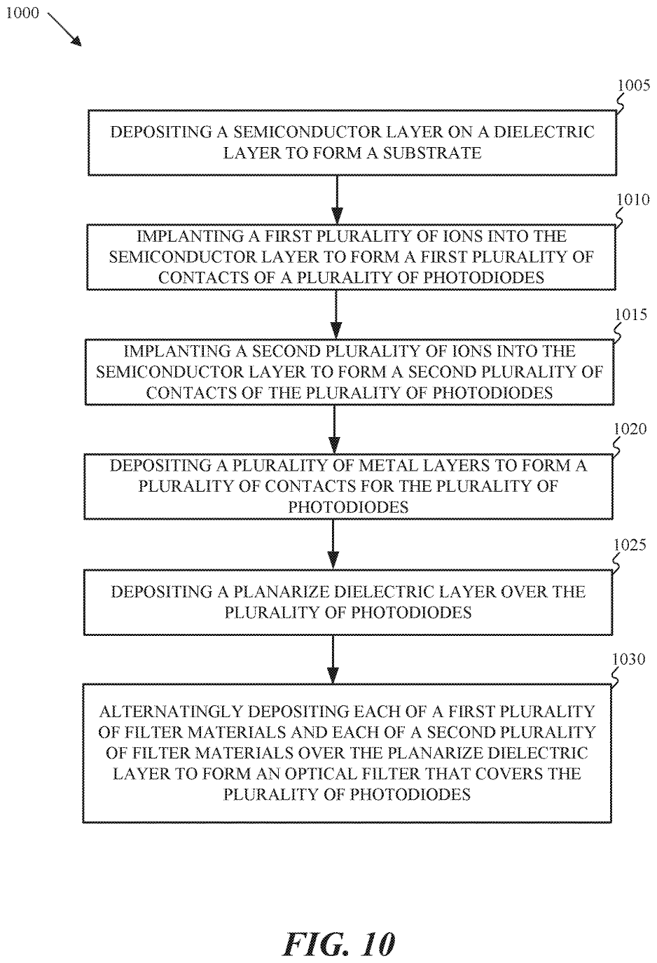

FIG. 10 illustrates an example of a method 1000 for manufacturing the UV sensor device 300 (FIG. 3A) according to an aspect of the present disclosure.

At 1005, the method 1000 includes depositing a semiconductor layer on a dielectric layer to form a substrate. One or more of a CVD chamber and/or a PVD chamber is configured to, and/or provides means for, depositing a silicon layer on a silicon dioxide layer to form a SOI substrate.

At 1010, the method 1000 includes implanting a first plurality of ions into the semiconductor layer to form a first plurality of contacts of a plurality of photodiodes. An ion implanter is configured to, and/or provides means for, implanting a first plurality of ions into the silicon layer to form a first plurality of contacts of a plurality of photodiodes.

At 1015, the method 1000 includes implanting a second plurality of ions into the semiconductor layer to form a second plurality of contacts of the plurality of photodiodes. An ion implanter is configured to, and/or provides means for, implanting a second plurality of ions into the silicon layer to form a second plurality of contacts of the plurality of photodiodes.

At 1020, the method 1000 includes depositing a plurality of metal layers to form a plurality of contacts for the plurality of photodiodes. One or more of a sputterer, an evaporator, a CVD chamber, a PVD chamber, and/or an ALD chamber is configured to, and/or provides means for, depositing a plurality of metal layers to form a plurality of contacts for the plurality of photodiodes.

At 1025, the method 1000 includes depositing a planarize dielectric layer over the plurality of photodiodes. One or more of a sputterer, an evaporator, a CVD chamber, a PVD chamber, and/or an ALD chamber is configured to, and/or provides means for, depositing a planarize silicon dioxide over the plurality of photodiodes.

At 1030, the method 1000 includes alternatingly depositing each of a first plurality of filter materials and each of a second plurality of filter materials over the planarize dielectric layer to form an optical filter that covers the plurality of photodiodes. One or more of a sputterer, an evaporator, a CVD chamber, a PVD chamber, and/or an ALD chamber is configured to alternatingly depositing HfO₂ and Al over the planarize dielectric layer to form an optical filter that covers the plurality of photodiodes.

Aspects of the present disclosure includes a sensor device having a substrate, a photodiode device formed on the substrate, the photodiode device being configured to generate a photocurrent in response to being irradiated with sunlight, and an optical filter device formed on a passivation layer and deposited over the photodiode device, the optical filter device having a first plurality of layers of a conducting material, a second plurality of layers of a dielectric material, wherein the first plurality of layers and the second plurality of layers stacked alternatingly, and wherein the optical filter device is configured to match at least a portion of the erythemal curve, resulting in the photocurrent generated by the photodiode device being a representation of a UV index.

Aspects of the present disclosure include the sensor device above, wherein the substrate is a silicon-on-insulator (SOI) substrate having a device layer formed thereon, with the photodiode device formed on the device layer.

Aspects of the present disclosure include any of the sensor devices above, wherein the device layer has a thickness of 300 nanometers (nm).

Aspects of the present disclosure include any of the sensor devices above, wherein the conducting material comprises aluminum (Al), gallium (Ga), magnesium (Mg), or rhodium (Rh).

Aspects of the present disclosure include any of the sensor devices above, wherein the conducting material has a UV absorption value lower than a threshold value.

Aspects of the present disclosure include any of the sensor devices above, wherein the dielectric material comprises HfO₂, SiO₂, or Al₂O₃.

Aspects of the present disclosure include any of the sensor devices above, wherein a first number of the first plurality of layers is equal to a second number of the second plurality of layers.

Aspects of the present disclosure include any of the sensor devices above, wherein the first number of the first plurality of layers or the second number of the second plurality of layers is equal to 4, 5, 6, 7, or 8.

Aspects of the present disclosure include any of the sensor devices above, further comprising a plurality of photodiode device formed sequentially along the substrate.

Aspects of the present disclosure include any of the sensor devices above, further comprising an edge protection structure.

Aspects of the present disclosure include any of the sensor devices above, wherein the edge protection structure includes a metal trench surrounding at least a portion of the photodiode device.

Aspects of the present disclosure include any of the sensor devices above, further comprising a plurality of photodiode devices formed on the substrate.

Aspects of the present disclosure includes a method of manufacturing a sensor device including depositing a semiconductor layer on a dielectric layer to form a substrate, implanting a first plurality of ions into the semiconductor layer to form a first plurality of contacts of a plurality of photodiodes, implanting a second plurality of ions into the semiconductor layer to form a second plurality of contacts of the plurality of photodiodes, depositing a plurality of metal layers to form a plurality of contacts for the plurality of photodiodes, depositing a planarize dielectric layer over the plurality of photodiodes, and alternatingly depositing each of a first plurality of filter materials and each of a second plurality of filter materials over the planarize dielectric layer to form an optical filter that covers the plurality of photodiodes, the optical filter being configured to match at least a portion of the erythemal curve.

Aspects of the present disclosure include the method above, further comprising, prior to depositing the plurality of metal layers, depositing an insulating layer over the semiconductor layer, and patterning a plurality of vias for the plurality of metal layers to contact the semiconductor layer.

Aspects of the present disclosure include any of the methods above, further comprising depositing a layer of photoresist prior to alternatingly depositing each of the first plurality of filter materials and each of the second plurality of filter materials, and lifting off the photoresist after depositing each of the first plurality of filter materials and each of the second plurality of filter materials.

Aspects of the present disclosure include any of the methods above, further comprising forming an edge protection structure.

Aspects of the present disclosure include any of the methods above, wherein forming an edge protection structure comprises forming a metal trench surrounding at least a portion of the plurality of photodiodes.

Aspects of the present disclosure include any of the methods above, wherein the substrate is a silicon-on-insulator (SOI) substrate.

Aspects of the present disclosure include any of the methods above, wherein the semiconductor layer is a silicon layer having a thickness of 300 nanometers (nm).

Aspects of the present disclosure include any of the methods above, wherein the first plurality of filter materials comprises aluminum (Al), gallium (Ga), magnesium (Mg), or rhodium (Rh).

Aspects of the present disclosure include any of the methods above, wherein the first plurality of filter materials has a UV absorption value lower than a threshold value.

Aspects of the present disclosure include any of the methods above, wherein the second plurality of materials comprises HfO₂, SiO₂, or Al₂O₃.

Aspects of the present disclosure include any of the methods above, wherein a first number of layers of the first plurality of materials is equal to a second number of layers of the second plurality of materials.

Aspects of the present disclosure include any of the methods above, wherein the first number of layers or the second number of layers is equal to 4, 5, 6, 7, or 8.

Unless otherwise expressly stated, it is in no way intended that any protocol, procedure, process, or method set forth herein be construed as requiring that its acts or steps be performed in a specific order. Accordingly, where a process or method claim does not actually recite an order to be followed by its acts or steps or it is not otherwise specifically recited in the claims or descriptions of the subject disclosure that the steps are to be limited to a specific order, it is in no way intended that an order be inferred, in any respect. This holds for any possible non-express basis for interpretation, including: matters of logic with respect to the arrangement of steps or operational flow; plain meaning derived from grammatical organization or punctuation; the number or type of aspects described in the specification or annexed drawings; or the like.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in this specification and annexed drawings and Appendix should be construed to mean “one or more” unless specified otherwise or clear from context to be directed to a singular form.

In addition, the terms “example” and “such as” are utilized herein to mean serving as an instance or illustration. Any aspect or design described herein as an “example” or referred to in connection with a “such as” clause is not necessarily to be construed as preferred or advantageous over other aspects or designs described herein. Rather, use of the terms “example” or “such as” is intended to present concepts in a concrete fashion. The terms “first,” “second,” “third,” and so forth, as used in the claims and description, unless otherwise clear by context, is for clarity only and does not necessarily indicate or imply any order in time or space.

Various aspects described herein can be implemented as a method, device, system, apparatus, or article of manufacture using standard programming and/or engineering techniques. In addition, various of the aspects disclosed herein also can be implemented by means of program modules or other types of computer program instructions stored in a memory device and executed by a processor, or other combination of hardware and software, or hardware and firmware. Such program modules or computer program instructions can be loaded onto a general purpose computer, a special purpose computer, or another type of programmable data processing apparatus to produce a machine, such that the instructions which execute on the computer or other programmable data processing apparatus create a means for implementing the functionality of disclosed herein.

What has been described above includes examples of one or more aspects of the disclosure. It is, of course, not possible to describe every conceivable combination of components or methodologies for purposes of describing these examples, and it can be recognized that many further combinations and permutations of the present aspects are possible. Accordingly, the aspects disclosed and/or claimed herein are intended to embrace all such alterations, modifications and variations that fall within the spirit and scope of the detailed description and the appended claims. Furthermore, to the extent that one or more of the terms “includes,” “including,” “has,” “have,” or “having” is used in either the detailed description or the claims, such term is intended to be inclusive in a manner similar to the term “comprising” as “comprising” is interpreted when employed as a transitional word in a claim.

What we claim is:

1. A sensor device, comprising:
a substrate;
a photodiode device formed on the substrate, the photodiode device being configured to generate a photocurrent in response to being irradiated with sunlight; and
an optical filter device formed on a passivation layer and deposited over the photodiode device, the optical filter device comprising,
a first plurality of layers of a conducting material;
a second plurality of layers of a dielectric material;
wherein the first plurality of layers and the second plurality of layers stacked alternatingly; and
wherein the optical filter device is configured to match at least a portion of the erythemal curve, resulting in the photocurrent generated by the photodiode device being a representation of a UV index.

2. The sensor device of claim 1, wherein the substrate is a silicon-on-insulator (SOI) substrate having a device layer formed thereon, with the photodiode device formed on the device layer.

3. The sensor device of claim 1, wherein the device layer has a thickness of 300 nanometers (nm).

4. The sensor device of concept 1, wherein the conducting material comprises aluminum (Al), gallium (Ga), magnesium (Mg), or rhodium (Rh).

5. The sensor device of claim 4, wherein the conducting material has a UV absorption value lower than a threshold value.

6. The sensor device of claim 1, wherein the dielectric material comprises HfO₂, SiO₂, or Al₂O₃.

7. The sensor device of claim 1, wherein a first number of the first plurality of layers is equal to a second number of the second plurality of layers.

8. The sensor device of claim 7, wherein the first number of the first plurality of layers or the second number of the second plurality of layers is equal to 4, 5, 6, 7, or 8.

9. The sensor device of claim 1, further comprising a plurality of photodiode device formed sequentially along the substrate.

10. The sensor device of claim 1, further comprising an edge protection structure.

11. The sensor device of claim 10, wherein the edge protection structure includes a metal trench surrounding at least a portion of the photodiode device.

12. The sensor device of claim 1, further comprising a plurality of photodiode devices formed on the substrate.
